(19) United States
(12) Patent Application Publication
(10) Pub. No.: US 2025/0183178 A1
(43) Pub. Date: Jun. 5, 2025

(54) BRIDGE DIE IN SUBSTRATE CORE LAYER

(71) Applicant: QUALCOMM Incorporated, San Diego, CA (US)

(72) Inventors: Joan Rey Villarba BUOT, Escondido, CA (US); Hong Bok WE, San Diego, CA (US); Zhijie WANG, San Diego, CA (US); Sang-Jae LEE, San Diego, CA (US)

(21) Appl. No.: 18/524,571

(22) Filed: Nov. 30, 2023

(51) Int. Cl. H01L 23/538; H01L 23/00; H01L 25/18; H10B 80/00

(52) U.S. Cl. CPC H01L 23/5381; H01L 23/5383; H01L 23/5386; H01L 24/16; H01L 24/81; H01L 25/18; H10B 80/00; H01L 2224/16145; H01L 2224/16227; H01L 2224/81

(57) ABSTRACT

A substrate includes a core layer and a bridge die within the core layer. The bridge die includes first contacts and second contacts. The first contacts are electrically connected to the second contacts via conductive traces of the bridge die. The substrate also includes at least one dielectric layer on a surface of the core layer and the bridge die, third contacts on a surface of the at least one dielectric layer and electrically connected to the first contacts, and fourth contacts on the surface of the at least one dielectric layer and electrically connected to the second contacts.

### FIELD

Various features relate to integrated devices.

### BACKGROUND

Integrated circuit technology has achieved great strides in advancing computing power through miniaturization of active components. As integrated circuits become more complex, more interconnect layers are used to provide electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to signal routing and thermal issues when multiple dies are arranged within the small form factor.

As an example, a package-on-package (PoP) configuration can be used to interconnect an application processor with a memory package while maintaining a small form factor. However, as application processors become more powerful, such PoP configurations can become increasingly susceptible to thermal issues due to the restricted dissipation of the heat generated by the application processor.

Alternatively, the application processor and the memory package can be arranged on a substrate in a side-by-side package configuration. The thermal issues associated with PoP configurations are relieved by the improved heat dissipation in the side-by-side configuration. However, as improvements in memory capacities results in increasing numbers of input/output (I/O) pins of the memory interfaces, such side-by-side package configurations require relatively long traces and high-density routing from the application processor to the memory package. For example, routing between the application processor and the memory can require traces in the substrate having a 5 micron (μm) line and space (5/5 μm), 6/8 μm, or 4/4 μm, as illustrative examples, with some traces having lengths greater than 10 millimeters (mm), pushing the limits of routing capability of the substrate and resulting in low yields. In addition, such high-density routing requires a large number of substrate layers, resulting in significant expense.

### SUMMARY

Various features relate to integrated circuit (IC) devices.

One example provides an integrated device that includes a substrate. The substrate includes a core layer and a bridge die within the core layer. The bridge die includes first contacts and second contacts. The first contacts are electrically connected to the second contacts via conductive traces of the bridge die. The substrate also includes at least one dielectric layer on a surface of the core layer and the bridge die, third contacts on a surface of the at least one dielectric layer and electrically connected to the first contacts, and fourth contacts on the surface of the at least one dielectric layer and electrically connected to the second contacts.

Another example provides a device that includes a substrate. The substrate includes a core layer and a bridge die within the core layer. The bridge die includes first contacts and second contacts. The first contacts are electrically connected to the second contacts via conductive traces of the bridge die. The substrate also includes at least one dielectric layer on a surface of the core layer and the bridge die, third contacts on a surface of the at least one dielectric layer and electrically connected to the first contacts, and fourth contacts on the surface of the at least one dielectric layer and electrically connected to the second contacts. The device includes a first die including fifth contacts electrically connected to the third contacts. The device also includes a second die including sixth contacts electrically connected to the fourth contacts.

Another example provides a method for fabricating an integrated device. The method includes forming a first set of conductive lines. The method includes embedding, within a core layer of a substrate, a bridge die that includes first contacts electrically coupled to second contacts via conductive traces of the bridge die. The method includes forming at least one dielectric layer on a surface of the core layer and the bridge die. The method includes electrically connecting the first contacts to third contacts on a surface of the at least one dielectric layer. The method also includes electrically connecting the second contacts to fourth contacts on the surface of the at least one dielectric layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross sectional profile view of a device that includes a bridge die embedded in a core layer of a substrate and also illustrates a schematic top view of the bridge die.

FIG. 2 illustrates a schematic cross sectional profile view of a device that includes a bridge die embedded in a core layer of a substrate and also illustrates a schematic bottom view of a first die and a second die of the device.

FIGS. 3A and 3B illustrate an exemplary sequence for fabricating an exemplary device that includes a bridge die embedded in a core layer of a substrate.

FIG. 4 illustrates an exemplary flow diagram of a method for fabricating an exemplary device that includes a bridge die embedded in a core layer of a substrate.

FIG. 5 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

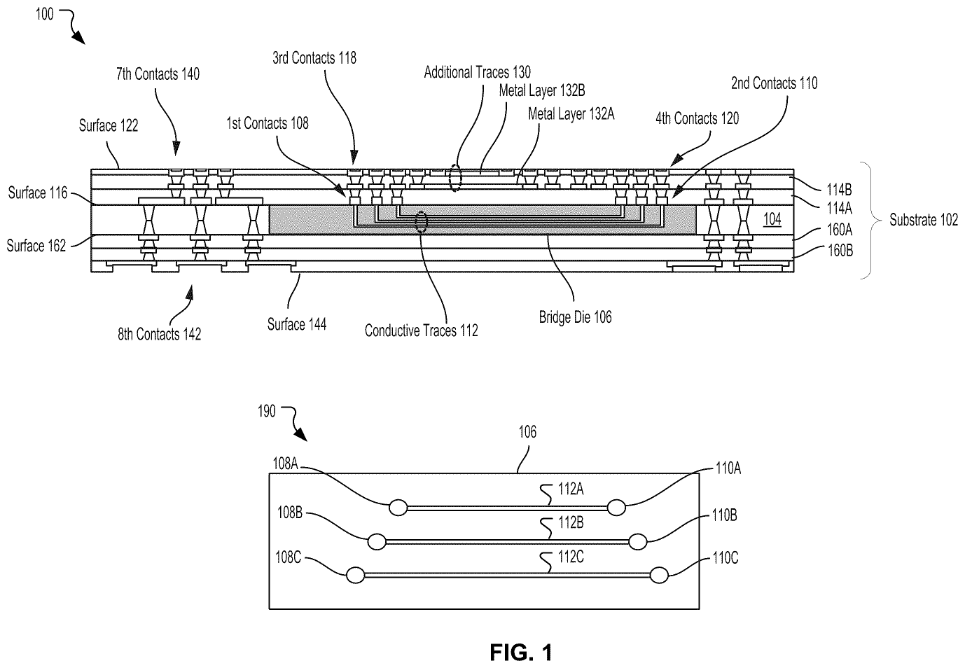

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1, multiple dielectric layers 114 are illustrated and associated with reference numbers 114A and 114B. When referring to a particular one of these dielectric layers, such as a dielectric layer 114A, the distinguishing letter “A” is used. However, when referring to any arbitrary one of these dielectric layers or to these dielectric layers as a group, the reference number 114 is used without a distinguishing letter.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to an integrated device that has a bridge die embedded in a core layer of a substrate. The bridge die can include conductive traces through silicon that enable routing of signals between multiple dies on the surface of the substrate that are electrically connected to the conductive traces via one or more contacts. Because long conductive traces with fine line and spacing (e.g., 5/5 μm) can be more reliably formed in the embedded bridge die as compared to using conventional techniques to form conventional traces in a substrate, substrate yield is improved. In addition, the substrate metal layer routing is reduced, further improving the substrate yield and reducing the number of metal layers needed, allowing the use of thinner substrates and reduced substrate cost.

### Exemplary Device Including an Integrated Device Comprising a Bridge Die in a Substrate Core Layer

FIG. 1 illustrates a schematic cross sectional profile view of an integrated device 100 that includes an exemplary substrate 102 that includes a bridge die 106 in a core layer 104. The substrate 102 also includes at least one dielectric layer 114 on a surface 116 (e.g., a top surface) of the core layer 104 and the bridge die 106, illustrated as dielectric layers 114A and 114B. At least one second dielectric layer 160 is on a second surface 162 (e.g., a bottom surface) of the core layer 104 and the bridge die 106, illustrated as dielectric layers 160A and 160B.

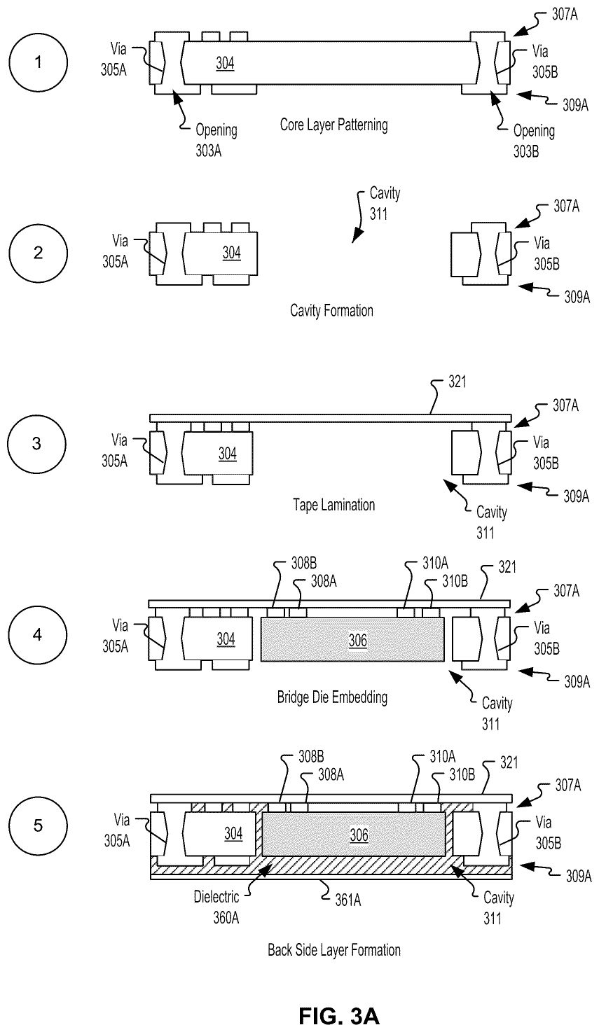

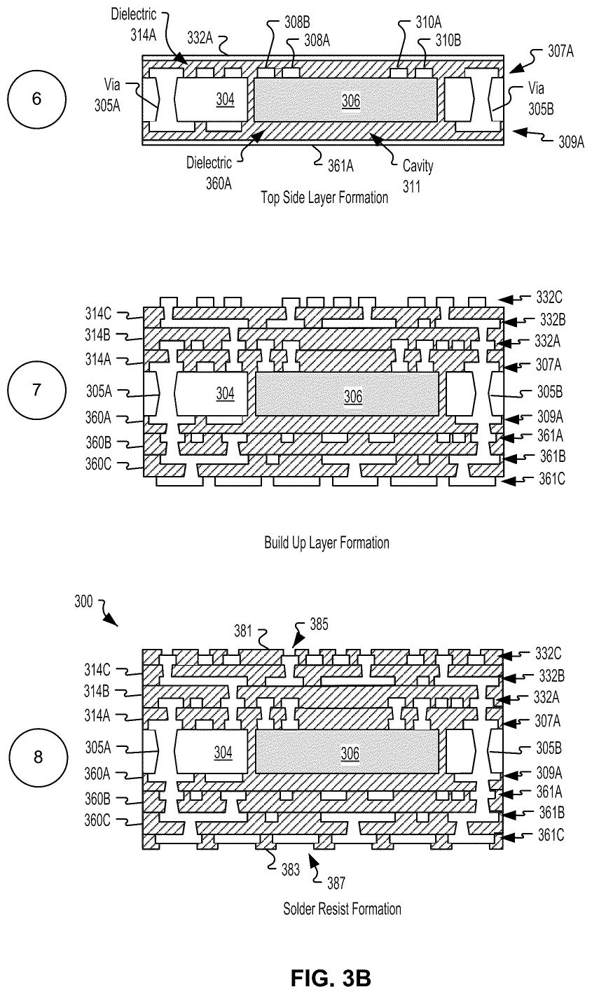

According to an aspect, the bridge die 106 is embedded within the core layer 104. In an example, the core layer 104 includes a composite material, such as an epoxy glass laminate material, and the bridge die 106 is inserted into a cavity of the core layer 104, as described further with reference to FIG. 3A. In some implementations, the bridge die 106 includes a silicon die; however, in other implementations the bridge die 106 can include one or more other materials with finer line and space capabilities than the dielectric layer 114 (such as glass or ceramic materials).

The bridge die 106 includes first contacts 108, second contacts 110, and conductive traces 112. The first contacts 108 are electrically connected to the second contacts 110 via the conductive traces 112 of the bridge die. As illustrated in a schematic top view 190 of the bridge die 106, the first contacts 108 include first contacts 108A, 108B, and 108C, which are electrically connected to corresponding second contacts 110A, 110B, and 110C via conductive traces 112A, 112B, and 112C, respectively. Although three first contacts 108, three second contacts 110, and three conductive traces 112 are illustrated, in other implementations the bridge die 106 may include any number of first contacts 108, any number of second contacts 110, and any number of conductive traces 112, as described further below.

The conductive traces 112 may have a single-layer or a multi-layer configuration. Multi-layer configurations provide the benefit of higher routing density of the conductive traces 112, while single-layer configurations provide the benefit of reduced complexity and cost as compared to multi-layer configurations. According to an aspect, the bridge die 106 is devoid of active circuitry. To illustrate, the bridge die 106 includes the contacts 108, 110 and the conductive traces 112 for signal routing, but does not include any transistors.

The substrate 102 also includes third contacts 118 and fourth contacts 120 on a surface 122 (e.g., an upper surface) of the dielectric layer 114. The third contacts 118 are electrically connected to the first contacts 108 by one or more conductive vias and metal layers of the dielectric layer 114. The fourth contacts 120 are electrically connected to the second contacts 110 by one or more conductive vias and metal layers of the dielectric layer 114.

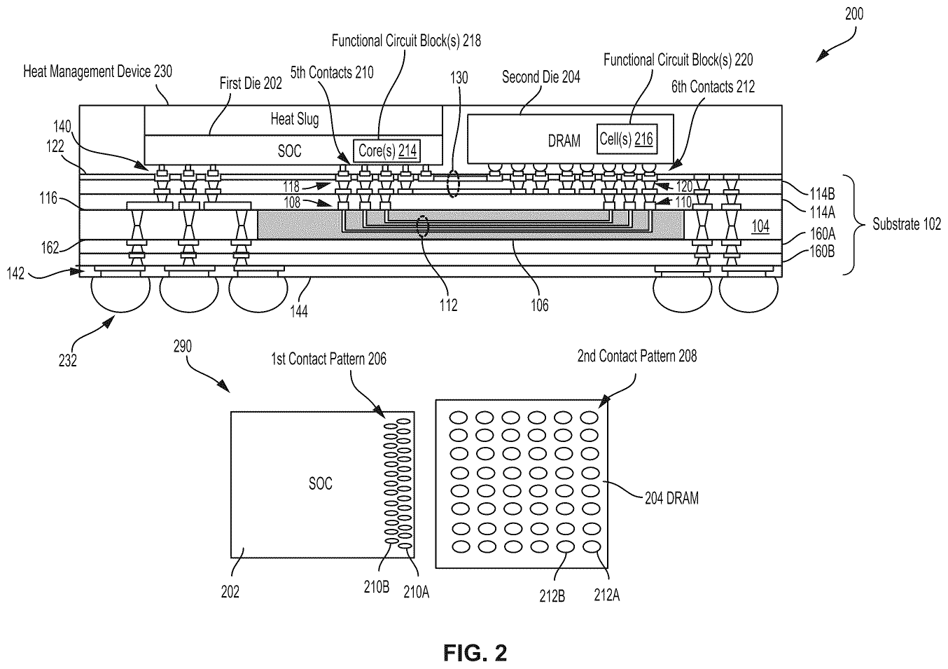

As described further with reference to FIG. 2, the conductive traces 112 can be configured to propagate signals between a first die and a second die (not shown) that are in a side-by-side configuration on the surface 122 of the substrate 102. For example, the first die (e.g., an application processor) can include fifth contacts that are electrically connected to the third contacts 118, and the second die (e.g., a memory die) can include sixth contacts that are electrically connected to the fourth contacts 120.

The third contacts 118 can be arranged to match a first contact pattern of the first die, and the fourth contacts 120 can be arranged to match a second contact pattern of the second die. In a particular example, the longest signal paths between the first die and the second die are carried by the conductive traces 112, while shorter signal paths are carried in one or more metal layers 132 defining additional conductive traces 130 configured to propagate additional signals between the first die and the second die. As illustrated, the additional conductive traces 130 are formed in a metal layer 132A of the dielectric layer 114A and in a metal layer 132B of the dielectric layer 114B and are configured to electrically connect one or more contacts of the first die to one or more contacts of the second die. According to an aspect, the conductive traces 112 of the bridge die 106 are longer than the additional conductive traces 130.

Optionally, the integrated device 100 also includes one or more sets of additional contacts and vias that form electrical connections between the surface 122 of the dielectric layer 114 and a surface 144 of the second dielectric layer 160. For example, one or more seventh contacts 140 are on the surface 122 of the dielectric layer 114, and one or more eighth contacts 142, such as for a ball grid array (BGA), are on the surface 144 of the second dielectric layer 160. The seventh contacts 140 are electrically connected to respective contacts of the eighth contacts 142 via one or more signal paths through the substrate.

Using the conductive traces 112 in the bridge die 106 enables longer conductive traces, with finer lines and spacing, than can reliably be formed in metal layers 132 of the substrate 102 using conventional techniques. As a result, substrate yield is improved. In addition, routing in the metal layer 132 of the substrate 102 is reduced, further improving the substrate yield and reducing the number of metal layers 132 needed, allowing the use of a thinner substrate 102 and reduced cost.

Although the bridge die 106 is illustrated as including the conductive traces 112 extending from one side of the bridge die 106 to the other side of the bridge die 106 to propagate signals between a first die that is electrically connected to the first contacts 108 and a second die that is electrically connected to the second contacts 110, in other implementations the bridge die 106 may include additional conductive traces that extend in one or more other directions, or that extend beyond the first contacts 108 or the second contacts 110, and that are electrically connected to one or more additional sets of contacts on the bridge die 106 to enable signal routing between three or more dies that are coupled to the substrate 102. Thus, the arrangement and description of the conductive traces 112 and the contacts (e.g., the first contacts 108 and the second contacts 110) of the bridge die 106 should be considered exemplary and not limiting.

FIG. 2 illustrates a schematic cross sectional profile view of a device 200 that includes a substrate that includes a bridge die in a substrate core layer. The device of FIG. 2 includes many of the same components and features as are described above with reference to FIG. 1. Such components and features are physically and operationally the same as described above with reference to FIG. 1 and are labeled in FIGS. 2 using the same reference numbers.

FIG. 2 depicts a device 200 that includes a first die 202 and a second die 204 coupled to the substrate 102. The substrate 102 includes the core layer 104 and the bridge die 106 including the conductive traces 112. The first die 202 includes fifth contacts 210 that are electrically connected to the third contacts 118 of the substrate 102. The second die 204 includes sixth contacts 212 electrically connected to the fourth contacts 120 of the substrate 102. The first die 202 and the second die 204 have a side-by-side configuration on the surface 122 of the dielectric layer 114.

Each of the dies 202, 204 can include integrated circuitry, such as a plurality of transistors and/or other circuit elements. Components of the integrated circuitry can be formed in and/or over a semiconductor substrate. Different implementations can use different types of transistors to form active circuitry, such as a field effect transistor (FET), planar FET, finFET, a gate all around FET, or mixtures of transistor types. The active circuitry can be arranged and interconnected to form processing logic blocks (e.g., transistor blocks), memory blocks, etc. In addition to active circuitry, the integrated circuitry can also include a power distribution network (PDN). To illustrate, a PDN can include, for example, one or more power rails, one or more ground rails, etc. In some implementations, a front end of line (FEOL) process may be used to fabricate the integrated circuitry in and/or over the semiconductor substrate.

According to an aspect, the first die 202 is a first chiplet and the second die 204 is a second chiplet designed to operate in conjunction with the first chiplet. To illustrate, first circuitry of the first chiplet (e.g., the first die 202) includes one or more first functional circuit blocks 218, second circuitry of the second chiplet (e.g., the second die 204) includes one or more second functional circuit blocks 220, and the first functional circuit block(s) 218 and the second functional circuit block(s) 220 are operationally dependent upon one another. In the particular embodiment of FIG. 2, the first die 202 is a system-on-chip (SOC) that includes one or more processor cores 214 (e.g., an application processor), and the second die 204 is a dynamic random-access memory (DRAM) that includes one or more memory cells 216. A heat management device 230, illustrated as a heat slug, is configured to dissipate heat of at least the first die 202.

A bottom view 290 of the first die 202 and the second die 204 illustrates the first die 202 as having a flip-chip configuration including the fifth contacts 210 that are electrically connected to integrated circuitry of first die 202 and configured to couple to corresponding contacts of the third contacts 118. To illustrate, the fifth contacts 210 are arranged in a first contact pattern 206 that includes a first column of contacts including a representative contact 210A, and a second column of contacts including a representative contact 210B. The third contacts 118 are arranged to match the first contact pattern 206 of the first die 202.

Similarly, the second die 204 is illustrated as having a flip-chip configuration including the sixth contacts 212 that are electrically connected to integrated circuitry of second die 204 and configured to couple to corresponding contacts of the fourth contacts 120. To illustrate, the sixth contacts 212 are arranged in a second contact pattern 208 that includes a first column of contacts including a representative contact 212A, and a second column of contacts including a representative contact 212B. The fourth contacts 120 are arranged to match the second contact pattern 208 of the second die 204.

As illustrated, the conductive traces 112 of the bridge die 106 and the additional conductive traces 130 of the metal layers of the substrate 102 are configured to propagate signals between the first die 202 and the second die 204. The conductive traces 112 of the bridge die are longer than the additional conductive traces 130 and electrically connect the contacts of first contact pattern 206 of the first die 202 that are farthest from the second die 204 (e.g., contact 210B) to corresponding contacts of the second contact pattern 208 of the second die 204 that are farthest from the first die 202 (e.g., contact 212A). The additional conductive traces 130 electrically connect contacts of first contact pattern 206 of the first die 202 that are closest to corresponding contacts of the second contact pattern 208 of the second die 204, so that the additional conductive traces are relatively short and can be formed with little to no negative impact on the yield of the substrate 102.

FIG. 2 also illustrates that the seventh contacts 140 on the surface 122 of the dielectric layer 114 can also be coupled to contacts of the first die 202 to enable routing of signals from the first die 202 via signal paths through the substrate 102 to respective balls 232 of a ball grid array via corresponding contacts of the eighth contacts 142. While FIG. 1 and FIG. 2 illustrate examples of devices having particular arrangements of the core layer 104, the bridge die 106, and dielectric layers 114 and 160, other implementations may include one or more additional layers, one or more fewer layers, or one or more different layers. For example, the dielectric layers 114 and the second dielectric layers 160 may each include any number of dielectric layers (e.g., a single layer, two layers, three layers, etc.) in conjunction with any corresponding number of metal layers. Further, while FIG. 2 illustrates the substrate 102 used in conjunction with an SOC and a DRAM, in other examples the substrate 102 may be used in conjunction with any type of active and/or passive devices.

### Exemplary Sequence for Fabricating an Integrated Device Including a Bridge Die in a Substrate Core Layer

In some implementations, fabricating an integrated device 300 that includes a bridge die in a substrate core layer (e.g., the integrated device 100 or the device 200) includes several processes. FIGS. 3A and 3B illustrate an exemplary sequence for providing or fabricating an integrated device that includes a bridge die in a substrate core layer, as described with reference to any of FIGS. 1-2. In some implementations, the sequence of FIGS. 3A and 3B may be used to provide (e.g., during fabrication of) one or both of the devices 100 or 200.

It should be noted that the sequence of FIGS. 3A and 3B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A and 3B.

Stage 1 of FIG. 3A illustrates a state after core layer 304 has been patterned. Openings 303A, 303B can be formed in the core layer 304 using patterning operations, etching processes, drilling operations, laser ablation operations, other targeted removal operations, or combinations thereof. Vias 305A, 305B may be formed by applying a metal material (e.g., copper) into the openings 303A, 303B. In a particular implementation, the core layer 304 is a composite material including glass fiber, resin, and filler material, such as an FR-4 type epoxy glass laminate. In an example, the core layer 304 is a copper-clad laminate (CCL) that includes cured material with copper foil forming metal layers 307A, 309A. The metal layers 307A, 309A may be patterned using a photoresist process to generate a pattern to guide an etching process to form conductive lines in the metal layers 307A, 309A, and a photoresist ashing or stripping operation may be performed to remove the photoresist layer(s) after formation of the conductive lines. Although not shown in the accompanying figures, such photoresist layers can be used during metal deposition and/or etching processes. Similarly, other processing steps may be performed, such as cleaning, planarization, etc., that may also be omitted from the accompanying figures and/or description. According to an aspect, the core layer 304 corresponds to the core layer 104 of FIG. 1.

Stage 2 illustrates a state after formation of a cavity 311 in the core layer 304. For example, the cavity 311 may be formed by using a laser process.

Stage 3 illustrates a state after a tape 321 has been applied to the metal layer 307A. The tape 321 may be applied using a tape lamination process.

Stage 4 illustrates a state after embedding a bridge die 306 in the core layer 304. In a particular implementation, the bridge die 306 includes first contacts 308 including representative contacts 308A and 308B, second contacts 310 including representative contacts 310A and 310B, and conductive traces (not shown) electrically connecting the first contacts 308 to the second contacts 310. The bridge die 306 may include or be formed of silicon, and the contacts 308, 310 and conductive traces may be formed using conventional semiconductor processing techniques. Alternatively, the bridge die 306 may include or be formed of any other suitable material that supports formation of the conductive traces having fine line and space (e.g., 5/5 μs) and lengths that may exceed 10 mm, with high yield. The bridge die 306 may be embedded in the core layer 304 by inverting the core layer 304 and tape 321 assembly so that the tape 321 is beneath the core layer 304, and placing the bridge die 306 into the cavity 311 so that the contacts 308, 310 adhere to the tape 321. In some implementations, the bridge die 306 corresponds to the bridge die 106 of FIG. 1, the first contacts 308 correspond to the first contacts 108, and the second contacts 310 correspond to the second contacts 110.

Stage 5 illustrates a state after a back side layer formation process has been performed in which a dielectric layer 360A is formed on a back surface of the core layer 304 and the bridge die 306. The material of the dielectric layer 360A extends into the cavity 311 and fills gaps in the cavity 311 that may otherwise trap air. A metal layer 361A is formed on a surface of the dielectric layer 360A. In a particular example, the dielectric layer 360A corresponds to a prepreg material, such as a laminate composite of fiber sheets that are impregnated with polymer resins that have not been fully cured, and the metal layer 361A corresponds to a copper foil layer of the prepreg material. To illustrate, the dielectric layer 360A can include an Ajinomoto build-up film (ABF) or another resin-based material. The dielectric layer 360A and the metal layer 361A may be applied by inverting the core layer 304 and tape 321 assembly so that the tape 321 is beneath the core layer 304 and performing a prepreg lamination process to the exposed surface of the core layer 304 and the bridge die 306. According to an aspect, the dielectric layer 360A corresponds to the dielectric layer 160A of FIG. 1.

Stage 6 illustrates a state after a top side layer formation process has been performed in which a dielectric layer 314A is formed on a top surface of the core layer 304 and the bridge die 306. A metal layer 332A is formed on a surface of the dielectric layer 314A. In a particular example, the dielectric layer 314A corresponds to a prepreg material, and the metal layer 332A corresponds to a copper foil layer of the prepreg material. In some implementations, the dielectric layer 314A can include an Ajinomoto build-up film (ABF) or another resin-based material. The tape 321 may be removed to expose the top surface of the core layer 304 and the bridge die 306, and the dielectric layer 314A and the metal layer 332A may be applied by performing a prepreg lamination process to the exposed surface of the core layer 304 and the bridge die 306. According to an aspect, the dielectric layer 314A corresponds to the dielectric layer 114A, and the metal layer 332A corresponds to the metal layer 132A, of FIG. 1.

Stage 7 illustrates a state after a build up layer formation process has been performed in which dielectric layers 314B and 314C and corresponding metal layers 332B and 332C have been formed on a top side of the device and dielectric layers 360B and 360C and corresponding metal layers 361B and 361C have been formed on a back side of the device. In a particular implementation, each of the dielectric layers 314B, 314C, 360B, and 360C correspond to a prepreg material, such as previously described for the dielectric layers 314A and 360A, and each of the metal layers 332B, 332C, 361B, and 361C corresponds to a copper foil layer of the prepreg material, such as previously described for the metal layers 332A and 361A. In an example, the dielectric layer 314B and the metal layer 332B may be applied by lamination of prepreg material to the surface of the dielectric layer 314A and the metal layer 332A. One or more openings can be formed through the dielectric layer 314B and the metal layer 332B and extending to the metal layer 332A using laser operations, patterning operations, etching processes, drilling operations, other targeted removal operations, or combinations thereof. A metal deposition process can be used to deposit conductive material (e.g., copper) in the openings to form conductive vias between the metal layer 332A and 332B, followed by patterning of the metal layer 332B using a lithography process.

After forming the dielectric layer 314B and the metal layer 332B, a similar process may be performed to form the dielectric layer 314C, the metal layer 332C, and conductive vias between the metal layer 332B and 332C. The device may next be inverted, and a similar process may be performed to form the dielectric layer 360B, the metal layer 361B, and conductive vias between the metal layer 361A and 361B, followed by formation of the dielectric layer 360C, the metal layer 361C, and conductive vias between the metal layer 361B and 361C. According to an aspect, the dielectric layer 314B corresponds to the dielectric layers 114B, the dielectric layer 360B corresponds to the dielectric layers 160B, and the metal layer 332B corresponds to the metal layer 132B, of FIG. 1.

Stage 8 of FIG. 3B illustrates a state after formation of solder resist layers 381 and 383. For example, the solder resist layer 381 is formed on the dielectric layer 314C and metal layer 332C and patterned to form openings, such as an opening 385, exposing portions of a surface of the metal layer 332C. Similarly, the solder resist layer 383 is formed on the dielectric layer 360C and metal layer 361C and patterned to form openings, such as an opening 387, exposing portions of a surface of the metal layer 361C. In a particular implementation, the solder resist layers 381 and 383 correspond to ABF or another resin-based material without glass that provides finer line and space capability than conventional prepreg materials. The openings 385 and 387 can be formed using patterning operations, etching processes, drilling operations, laser ablation operations, other targeted removal operations, or combinations thereof. According to an aspect, at least some of the exposed portions of the metal layer 332C are configured to be electrically connected to one or more contacts (e.g., flip chip bumps) of one or more dies, such as the first die 202 and/or the second die 204 of FIG. 2. At least some of the exposed portions of the metal layer 361 are configured to be electrically connected to a ball grid array (BGA).

Formation of the integrated device 300 is completed after Stage 8 of FIG. 3B. However, in some implementations, one or more of Stages 1-8 can be modified or skipped, one or more stages added, or a combination thereof. To illustrate, in a first example, Stage 7 can be modified to include additional or fewer dielectric layers and corresponding metal layers than have been described above.

### Exemplary Flow Diagram of a Method for Fabricating an Integrated Device Comprising a Bridge Die in a Substrate Core Layer

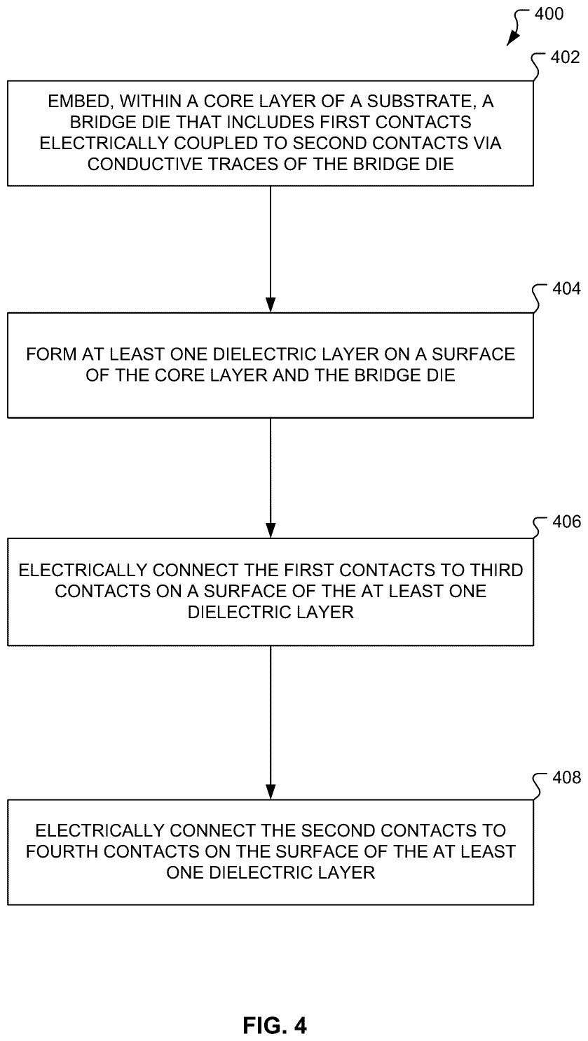

In some implementations, fabricating an integrated device that includes a bridge die in a substrate core layer includes several processes. FIG. 4 illustrates an exemplary flow diagram of a method 400 for providing or fabricating an integrated device that includes a bridge die in a substrate core layer (e.g., the integrated device 100 or the device 200). In some implementations, the method 400 of FIG. 4 may be used to provide or fabricate the integrated device 100 or the device 200.

It should be noted that the method 400 of FIG. 4 may combine one or more processes in order to simplify and/or clarify the method for providing or fabricating an integrated device. In some implementations, the order of the processes may be changed or modified.

The method 400 includes, at block 402, embedding, within a core layer of a substrate, a bridge die that includes first contacts electrically coupled to second contacts via conductive traces of the bridge die. According to an aspect, embedding the bridge die includes forming a cavity in the core layer, and inserting the bridge die into the cavity. For example, the bridge die can correspond to the bridge die 106, and the core layer can correspond to the core layer 104 of FIG. 1. In some implementations, Stages 1-4 of FIG. 3A illustrate and describe an example of embedding a bridge die by forming a cavity in a core layer and inserting the bridge die into the cavity.

The method 400 includes, at block 404, forming at least one dielectric layer on a surface of the core layer and the bridge die. For example, the at least one dielectric layer can correspond to the at least one dielectric layer 114 of FIG. 1. In some implementations, Stages 6 and 7 of FIG. 3B illustrate and describe an example of forming one or more dielectric layers on a surface of the core layer and the bridge die.

The method 400 includes, at block 406, electrically connecting the first contacts to third contacts on a surface of the at least one dielectric layer. For example, the first contacts 108 of FIG. 1 are electrically coupled to the third contacts 118 that are on the surface of the dielectric layer 114B. In some implementations, Stage 7 of FIG. 3B illustrates and describes an example of electrically connecting the first contacts to third contacts on the surface of the at least one dielectric layer.

The method 400 also includes, at block 408, electrically connecting the second contacts to fourth contacts on the surface of the at least one dielectric layer. For example, the second contacts 110 of FIG. 1 are electrically coupled to the fourth contacts 120 that are on the surface of the dielectric layer 114B. In some implementations, Stage 7 of FIG. 3B illustrates and describes an example of electrically connecting the second contacts to fourth contacts on the surface of the at least one dielectric layer.

In some implementations, the method 400 includes electrically connecting fifth contacts of a first die to the third contacts, and electrically connecting sixth contacts of a second die to the fourth contacts. For example, the third contacts 118 are electrically connected to the fifth contacts 210 of the first die 202 of FIG. 2, and the fourth contacts 120 are electrically connected to the sixth contacts 212 of the second die 204. In a particular example, the first die is a first chiplet and the second die is a second chiplet.

The method 400 may also include forming additional conductive traces in metal layers of the substrate to provide additional signal paths between the first die and the second die via the metal layers. According to an aspect, the first die and the second die are arranged in a side-by-side configuration on the surface of the at least one dielectric layer. For example, the additional conductive traces 130 in the metal layers 132 of the substrate 102 provide additional signal paths between the first die 202 and the second die 204 in a side-by-side configuration. According to an aspect, the conductive traces of the bridge die are longer than the additional conductive traces. For example, each of the conductive traces 112 of the bridge die 106 is longer than the additional conductive traces 130.

In some implementations, the method 400 includes forming at least one second dielectric layer on a second surface of the core layer and the bridge die. For example, the at least one second dielectric layer 160 is formed on the second surface 162 of the core layer 104 and the bridge die 106. In some implementations, Stage 5 of FIG. 3A and Stage 7 of FIG. 3B illustrate and describe an example of forming at least one second dielectric layer on a second surface of a core layer and a bridge die. The method 400 may also include electrically connecting seventh contacts on the surface of the at least one dielectric layer and eighth contacts on a surface of the at least one second dielectric layer via one or more signal paths through the substrate. For example, the one or more seventh contacts 140 on the surface 122 of the at least one dielectric layer 114 are electrically connected to the one or more eighth contacts 142 on the surface 144 of the at least one second dielectric layer 160.

### Exemplary Electronic Devices

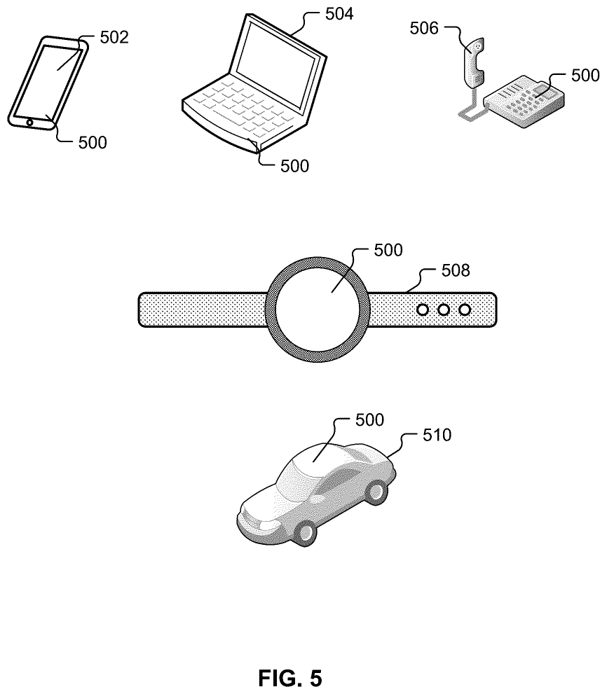

FIG. 5 illustrates various electronic devices that may include or be integrated with any of the devices 100, 200, or 300. For example, a mobile phone device 502, a laptop computer device 504, a fixed location terminal device 506, a wearable device 508, or a vehicle 510 (e.g., an automobile or an aerial device) may include a device 500. The device 500 can include, for example, the integrated device 100, the device 200, the integrated device 300, and/or the substrate 102 described herein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-5 may be rearranged and/or combined into a single component, process, feature or function or embodied in several components, processes, or functions. Additional elements, components, processes, and/or functions may also be added without departing from the disclosure. It should also be noted FIGS. 1-5 and its corresponding description in the present disclosure is not limited to dies and/or ICs. In some implementations, FIGS. 1-5 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component, or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an integrated device includes a substrate including: a core layer; a bridge die within the core layer and including first contacts and second contacts, the first contacts electrically connected to the second contacts via conductive traces of the bridge die; at least one dielectric layer on a surface of the core layer and the bridge die; third contacts on a surface of the at least one dielectric layer and electrically connected to the first contacts; and fourth contacts on the surface of the at least one dielectric layer and electrically connected to the second contacts.

Example 2 includes the integrated device of Example 1, wherein the conductive traces are configured to propagate signals between a first die and a second die on a surface of the substrate, and wherein the third contacts are arranged to match a first contact pattern of the first die and the fourth contacts are arranged to match a second contact pattern of the second die.

Example 3 includes the integrated device of Example 2, wherein the first die and the second die are in a side-by-side configuration on the surface of the substrate.

Example 4 includes the integrated device of Example 2 or Example 3, wherein the first die includes one or more processor cores and also includes fifth contacts arranged according to the first contact pattern, and wherein the second die includes one or more memory cells and also includes sixth contacts arranged according to the second contact pattern.

Example 5 includes the integrated device of any of Examples 2 to 4, wherein the first die is a first chiplet and the second die is a second chiplet designed to operate in conjunction with the first chiplet.

Example 6 includes the integrated device of Example 5, wherein first circuitry of the first chiplet includes one or more first functional circuit blocks and second circuitry of the second chiplet includes one or more second functional circuit blocks, and wherein the one or more first functional circuit blocks and the one or more second functional circuit blocks are operationally dependent upon one another.

Example 7 includes the integrated device of any of Examples 2 to 6, wherein the substrate further comprises one or more metal layers defining additional conductive traces configured to propagate additional signals from the first die to the second die.

Example 8 includes the integrated device of Example 7, wherein the conductive traces of the bridge die are longer than the additional conductive traces.

Example 9 includes the integrated device of any of Examples 1 to 8, wherein the bridge die is devoid of active circuitry.

Example 10 includes the integrated device of any of Examples 1 to 9, wherein the bridge die includes a silicon die.

Example 11 includes the integrated device of any of Examples 1 to 10, and further includes one or more seventh contacts on the surface of the at least one dielectric layer; at least one second dielectric layer on a second surface of the core layer and the bridge die; and one or more eighth contacts on a surface of the at least one second dielectric layer, the one or more seventh contacts electrically connected to the one or more eighth contacts via one or more signal paths through the substrate.

According to Example 12, a method of fabricating an integrated device includes embedding, within a core layer of a substrate, a bridge die that includes first contacts electrically coupled to second contacts via conductive traces of the bridge die; forming at least one dielectric layer on a surface of the core layer and the bridge die; electrically connecting the first contacts to third contacts on a surface of the at least one dielectric layer; and electrically connecting the second contacts to fourth contacts on the surface of the at least one dielectric layer.

Example 13 includes the method of Example 12, and further includes electrically connecting fifth contacts of a first die to the third contacts; and electrically connecting sixth contacts of a second die to the fourth contacts.

Example 14 includes the method of Example 12 or Example 13, wherein the conductive traces are configured to propagate signals between a first die and a second die on a surface of the substrate,

Example 15 includes the method of Example 13 or Example 14, wherein the third contacts are arranged to match a first contact pattern of the first die and the fourth contacts are arranged to match a second contact pattern of the second die.

Example 16 includes the method of any of Examples 13 to 15, wherein the first die includes one or more processor cores, and wherein the second die includes one or more memory cells.

Example 17 includes the method of any of Examples 13 to 16, wherein the first die is a first chiplet and the second die is a second chiplet.

Example 18 includes the method of Example 17, wherein first circuitry of the first chiplet includes one or more first functional circuit blocks and second circuitry of the second chiplet includes one or more second functional circuit blocks, and wherein the one or more first functional circuit blocks and the one or more second functional circuit blocks are operationally dependent upon one another.

Example 19 includes the method of any of Examples 13 to 18, wherein a heat management device dissipates heat of at least the first die.

Example 20 includes the method of any of Examples 13 to 19 and further includes forming additional conductive traces in metal layers of the substrate to provide additional signal paths between the first die and the second die via the metal layers.

Example 21 includes the method of Example 20, wherein the conductive traces of the bridge die are longer than the additional conductive traces.

Example 22 includes the method of any of Examples 12 to 21, wherein the first die and the second die are arranged in a side-by-side configuration on the surface of the at least one dielectric layer.

Example 23 includes the method of any of Examples 12 to 22, wherein embedding the bridge die includes: forming a cavity in the core layer; and inserting the bridge die into the cavity.

Example 24 includes the method of any of Examples 12 to 23, wherein the bridge die is devoid of active circuitry.

Example 25 includes the method of any of Examples 12 to 24, wherein the bridge die includes a silicon die.

Example 26 includes the method of any of Examples 12 to 25, and further includes forming at least one second dielectric layer on a second surface of the core layer and the bridge die; and electrically connecting seventh contacts on the surface of the at least one dielectric layer and eighth contacts on a surface of the at least one second dielectric layer via one or more signal paths through the substrate.

According to Example 27, a device includes a substrate including: a core layer; a bridge die within the core layer and including first contacts and second contacts, the first contacts electrically connected to the second contacts via conductive traces of the bridge die; at least one dielectric layer on a surface of the core layer and the bridge die; third contacts on a surface of the at least one dielectric layer and electrically connected to the first contacts; and fourth contacts on the surface of the at least one dielectric layer and electrically connected to the second contacts; a first die including fifth contacts electrically connected to the third contacts; and a second die including sixth contacts electrically connected to the fourth contacts.

Example 28 includes the device of Example 27, wherein the first die and the second die have a side-by-side configuration on the surface of the at least one dielectric layer.

Example 29 includes the device of Example 27 or Example 28, wherein the conductive traces are configured to propagate signals between the first die and the second die.

Example 30 includes the device of any of Examples 27 to 29, wherein the first die includes one or more processor cores and the second die includes one or more memory cells.

Example 31 includes the device of any of Examples 27 to 30, wherein the first die is a first chiplet and the second die is a second chiplet designed to operate in conjunction with the first chiplet.

Example 32 includes the device of Example 31, wherein first circuitry of the first chiplet includes one or more first functional circuit blocks and second circuitry of the second chiplet includes one or more second functional circuit blocks, and wherein the one or more first functional circuit blocks and the one or more second functional circuit blocks are operationally dependent upon one another.

Example 33 includes the device of any of Examples 27 to 32, wherein the substrate further comprises one or more metal layers defining additional conductive traces configured to propagate additional signals between the first die and the second die.

Example 34 includes the device of Example 33, wherein the conductive traces of the bridge die are longer than the additional conductive traces.

Example 35 includes the device of any of Examples 27 to 34 and further includes a heat management device configured to dissipate heat of at least the first die.

Example 36 includes the device of any of Examples 27 to 35, wherein the bridge die is devoid of active circuitry.

Example 37 includes the device of any of Examples 27 to 36, wherein the bridge die includes a silicon die.

Example 38 includes the device of any of Examples 27 to 37 and further includes one or more seventh contacts on the surface of the at least one dielectric layer; at least one second dielectric layer on a second surface of the core layer and the bridge die; and one or more eighth contacts on a surface of the at least one second dielectric layer, the one or more seventh contacts electrically connected to the one or more eighth contacts via one or more signal paths through the substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a substrate including:
a core layer;
a bridge die within the core layer and including first contacts and second contacts, the first contacts electrically connected to the second contacts via conductive traces of the bridge die;
at least one dielectric layer on a surface of the core layer and the bridge die;
third contacts on a surface of the at least one dielectric layer and electrically connected to the first contacts; and
fourth contacts on the surface of the at least one dielectric layer and electrically connected to the second contacts.

2. The integrated device of claim 1, wherein the conductive traces are configured to propagate signals between a first die and a second die on a surface of the substrate, and wherein the third contacts are arranged to match a first contact pattern of the first die and the fourth contacts are arranged to match a second contact pattern of the second die.

3. The integrated device of claim 2, wherein the first die and the second die are in a side-by-side configuration on the surface of the substrate.

4. The integrated device of claim 2, wherein the first die includes one or more processor cores and also includes fifth contacts arranged according to the first contact pattern, and wherein the second die includes one or more memory cells and also includes sixth contacts arranged according to the second contact pattern.

5. The integrated device of claim 2, wherein the first die is a first chiplet and the second die is a second chiplet designed to operate in conjunction with the first chiplet.

6. The integrated device of claim 5, wherein first circuitry of the first chiplet includes one or more first functional circuit blocks and second circuitry of the second chiplet includes one or more second functional circuit blocks, and wherein the one or more first functional circuit blocks and the one or more second functional circuit blocks are operationally dependent upon one another.

7. The integrated device of claim 2, wherein the substrate further comprises one or more metal layers defining additional conductive traces configured to propagate additional signals from the first die to the second die.

8. The integrated device of claim 7, wherein the conductive traces of the bridge die are longer than the additional conductive traces.

9. The integrated device of claim 1, wherein the bridge die is devoid of active circuitry.

10. The integrated device of claim 1, wherein the bridge die includes a silicon die.

11. The integrated device of claim 1, further comprising:
one or more seventh contacts on the surface of the at least one dielectric layer;
at least one second dielectric layer on a second surface of the core layer and the bridge die; and
one or more eighth contacts on a surface of the at least one second dielectric layer, the one or more seventh contacts electrically connected to the one or more eighth contacts via one or more signal paths through the substrate.

12. A method of fabricating an integrated device, the method comprising:
embedding, within a core layer of a substrate, a bridge die that includes first contacts electrically coupled to second contacts via conductive traces of the bridge die;
forming at least one dielectric layer on a surface of the core layer and the bridge die;
electrically connecting the first contacts to third contacts on a surface of the at least one dielectric layer; and
electrically connecting the second contacts to fourth contacts on the surface of the at least one dielectric layer.

13. The method of claim 12, further comprising:
electrically connecting fifth contacts of a first die to the third contacts; and
electrically connecting sixth contacts of a second die to the fourth contacts.

14. The method of claim 13, wherein the first die is a first chiplet and the second die is a second chiplet.

15. The method of claim 13, further comprising forming additional conductive traces in metal layers of the substrate to provide additional signal paths between the first die and the second die via the metal layers.

16. The method of claim 15, wherein the first die and the second die are arranged in a side-by-side configuration on the surface of the at least one dielectric layer, and wherein the conductive traces of the bridge die are longer than the additional conductive traces.

17. The method of claim 12, wherein embedding the bridge die includes:
forming a cavity in the core layer; and
inserting the bridge die into the cavity.

18. The method of claim 12, further comprising:
forming at least one second dielectric layer on a second surface of the core layer and the bridge die; and
electrically connecting seventh contacts on the surface of the at least one dielectric layer and eighth contacts on a surface of the at least one second dielectric layer via one or more signal paths through the substrate.

19. A device comprising:
a substrate including:
a core layer;
a bridge die within the core layer and including first contacts and second contacts, the first contacts electrically connected to the second contacts via conductive traces of the bridge die;
at least one dielectric layer on a surface of the core layer and the bridge die;
third contacts on a surface of the at least one dielectric layer and electrically connected to the first contacts; and
fourth contacts on the surface of the at least one dielectric layer and electrically connected to the second contacts;
a first die including fifth contacts electrically connected to the third contacts; and a second die including sixth contacts electrically connected to the fourth contacts.

20. The device of claim 19, wherein the first die and the second die have a side-by-side configuration on the surface of the at least one dielectric layer.

21. The device of claim 19, wherein the conductive traces are configured to propagate signals between the first die and the second die.

22. The device of claim 21, wherein the first die includes one or more processor cores and the second die includes one or more memory cells.

23. The device of claim 21, wherein the first die is a first chiplet and the second die is a second chiplet designed to operate in conjunction with the first chiplet.

24. The device of claim 23, wherein first circuitry of the first chiplet includes one or more first functional circuit blocks and second circuitry of the second chiplet includes one or more second functional circuit blocks, and wherein the one or more first functional circuit blocks and the one or more second functional circuit blocks are operationally dependent upon one another.

25. The device of claim 21, wherein the substrate further comprises one or more metal layers defining additional conductive traces configured to propagate additional signals between the first die and the second die.

26. The device of claim 25, wherein the conductive traces of the bridge die are longer than the additional conductive traces.

27. The device of claim 19, further comprising a heat management device configured to dissipate heat of at least the first die.

28. The device of claim 19, wherein the bridge die is devoid of active circuitry.

29. The device of claim 19, wherein the bridge die includes a silicon die.

30. The device of claim 19, further comprising:
one or more seventh contacts on the surface of the at least one dielectric layer,
at least one second dielectric layer on a second surface of the core layer and the bridge die; and
one or more eighth contacts on a surface of the at least one second dielectric layer, the one or more seventh contacts electrically connected to the one or more eighth contacts via one or more signal paths through the substrate.
